(19) United States
(12) Patent Application Publication
(10) Pub. No.: US 2013/0201768 A1
(43) Pub. Date: Aug. 8, 2013

(54) INTERNAL VOLTAGE GENERATING CIRCUIT, SEMICONDUCTOR MEMORY DEVICE INCLUDING THE SAME, AND METHOD OF GENERATING INTERNAL VOLTAGE

(71) Applicants: Sang-Hee KANG, Suwon-si (KR); Jong-Eun LEE, Hwaseong-si (KR); Dong-Su LEE, Hwaseong-si (KR)

(72) Inventors: Sang-Hee KANG, Suwon-si (KR); Jong-Eun LEE, Hwaseong-si (KR); Dong-Su LEE, Hwaseong-si (KR)

(73) Assignee: SAMSUNG ELECTRONICS CO., LTD., Suwon-si (KR)

(21) Appl. No.: 13/606,716

(22) Filed: Sep. 7, 2012

(30) Foreign Application Priority Data
Feb. 6, 2012 (KR) 10-2012-0011905

(51) Int. Cl. G11C 5/14; G05F 3/02

(52) U.S. Cl. 365/189.09; 327/540

(57) ABSTRACT

An internal voltage generating circuit and a semiconductor memory device including the internal voltage generating circuit are disclosed. The internal voltage generating circuit includes a first voltage generating circuit, a second voltage generating circuit, and a third voltage generating circuit. The first voltage generating circuit stabilizes a first external supply voltage to generate a first internal voltage. The second voltage generating circuit stabilizes the first external supply voltage and a second external supply voltage to generate a second internal voltage having a voltage level higher than the first internal voltage. The third voltage generating circuit stabilizes the second internal voltage to generate a third internal voltage having a voltage level lower than the second internal voltage. Accordingly, the semiconductor memory device may be insensitive to a change in an external supply voltage and have small power consumption.

### CROSS-REFERENCE TO RELATED APPLICATION

This application claims priority under 35 U.S.C. §119 to Korean Patent Application No. 10-2012-0011905 filed on Feb. 6, 2012, the entire contents of which are incorporated herein by reference in their entirety.

### BACKGROUND

1. Field

Embodiments of the inventive concepts relate to a semiconductor device, and particularly, to an internal voltage generating circuit of a semiconductor memory device.

2. Description of Related Art

In general, a semiconductor device includes an internal voltage generating circuit for generating internal voltages used in internal circuits. The internal voltage generating circuit stabilizes an external supply voltage so that the internal circuits operate safely.

However, the external supply voltage may change, therefore the output voltage of the internal voltage generating circuit may still vary according to the change in the external supply voltage. The internal voltage supplied to a memory cell array of a semiconductor memory device is required to have a constant value regardless of the change in the external supply voltage.

### SUMMARY

Embodiments of the inventive concepts provide an internal voltage generating circuit insensitive to a change in an external supply voltage and having low power consumption.

Embodiments of the inventive concepts also provide a semiconductor memory device including the internal voltage generating circuit.

Embodiments of the inventive concepts also provide a method of generating an internal voltage insensitive to a change in an external supply voltage and having low power consumption.

The embodiments of the inventive concepts are not limited to the above disclosure; other objectives may become apparent to those of ordinary skill in the art based on the following descriptions.

In accordance with an aspect of the inventive concepts, an internal voltage generating circuit includes a first voltage generating circuit, a second voltage generating circuit, and a third voltage generating circuit.

The first voltage generating circuit stabilizes a first external supply voltage to generate a first internal voltage. The second voltage generating circuit selectively stabilizes the first external supply voltage and a second external supply voltage to generate a second internal voltage having a voltage level higher than the first internal voltage. The third voltage generating circuit stabilizes the second internal voltage to generate a third internal voltage having a voltage level lower than the second internal voltage.

In an embodiment, the second voltage generating circuit may include a boosting circuit that boosts the voltage level of the first external supply voltage.

In another embodiment, at least one of the first voltage generating circuit, the second voltage generating circuit, and the third voltage generating circuit may be selectively activated in response to an operating mode of a semiconductor memory device.

In still another embodiment, the internal voltage generating circuit may further include a control circuit configured to generate an enable signal that selectively activates at least one of the first voltage generating circuit, the second voltage generating circuit, and the third voltage generating circuit based on operating mode signals of a semiconductor memory device.

In yet another embodiment, the operating mode signals of the semiconductor memory device may include an active command, a refresh command, and a test command.

In yet another embodiment, at least one of the first voltage generating circuit, the second voltage generating circuit, and the third voltage generating circuit may selectively be activated in response to a voltage level of the first external supply voltage.

In yet another embodiment, the internal voltage generating circuit may further include a control circuit configured to generate an enable signal that selectively activates at least one of the first voltage generating circuit, the second voltage generating circuit, and the third voltage generating circuit based on a voltage level of the first external supply voltage.

In yet another embodiment, at least one of the first voltage generating circuit, the second voltage generating circuit, and the third voltage generating circuit are configured to be selectively activated in response to an operating mode of a semiconductor memory device and a voltage level of the first external supply voltage.

In yet another embodiment, the internal voltage generating circuit may further include a first control circuit and a second control circuit.

The first control circuit generates a first enable signal that selectively activates at least one of the first voltage generating circuit, the second voltage generating circuit, and the third voltage generating circuit based on operating mode signals of a semiconductor memory device.

The second control circuit generates a second enable signal that selectively activates at least one of the first voltage generating circuit, the second voltage generating circuit, and the third voltage generating circuit based on a voltage level of the first external supply voltage.

In accordance with another aspect of the inventive concepts, a semiconductor memory device includes a memory cell array, a bit line sense amplifier, an internal voltage generating circuit and a sense amplifier driving circuit.

The memory cell array includes a plurality of word lines, a plurality of bit lines, and memory cells disposed at an intersection of each of the word lines and each of the bit lines. The bit line sense amplifier amplifies a voltage between the bit lines. The internal voltage generating circuit may include a first voltage generating circuit, a second voltage generating circuit, and a third voltage generating circuit. The sense amplifier driving circuit provides the first internal supply voltage or the second internal supply voltage to the bit line sense amplifier. The first voltage generating circuit stabilizes a first external supply voltage to generate a first internal voltage. The second voltage generating circuit stabilizes the first external supply voltage and a second external supply voltage to generate a second internal voltage having a voltage level higher than the first internal voltage. The third voltage generating circuit stabilizes the second internal voltage to generate a third internal voltage having a voltage level lower than the second internal voltage.

In an embodiment, the internal voltage generating circuit may further comprise a control circuit configured to generate an enable signal that selectively activates at least one of the first voltage generating circuit, the second voltage generating circuit, and the third voltage generating circuit based on operating mode signals of a semiconductor memory device.

In another embodiment, the internal voltage generating circuit may further comprise a control circuit configured to generate an enable signal that selectively activates at least one of the first voltage generating circuit, the second voltage generating circuit, and the third voltage generating circuit based on a voltage level of the first external supply voltage.

In still another embodiment, the internal voltage generating circuit may further comprise a first control circuit and a second control circuit. The first control circuit generates a first enable signal that selectively activates at least one of the first voltage generating circuit, the second voltage generating circuit, and the third voltage generating circuit based on operating mode signals of a semiconductor memory device. The second control circuit generates a second enable signal that selectively activates at least one of the first voltage generating circuit, the second voltage generating circuit, and the third voltage generating circuit based on a voltage level of the first external supply voltage.

In yet another embodiment, the semiconductor memory device may be a stacked memory device in which a plurality of chips transmits or receives data and control signals through a through-silicon-via (TSV).

In accordance with another aspect of the inventive concepts, a method of generating an internal voltage includes stabilizing a first external supply voltage to generate a first internal voltage, stabilizing the first external supply voltage and a second external supply voltage to generate a second internal voltage having a voltage level higher than the first internal voltage, and stabilizing the second internal voltage to generate a third internal voltage having a voltage level lower than the second internal voltage.

The internal voltage generating circuit according to embodiments of the inventive concepts may include a first voltage generating circuit configured to stabilize a first external supply voltage to generate a first internal voltage, a second voltage generating circuit configured to stabilize the first external supply voltage and a second external supply voltage to generate a second internal voltage having a voltage level higher than the first internal voltage, and a third voltage generating circuit configured to stabilize the second internal voltage to generate a third internal voltage having a voltage level lower than the second internal voltage.

Further, the internal voltage generating circuit according to embodiments of the inventive concepts may selectively activate blocks constructing the internal voltage generating circuit according to an operating mode of a semiconductor memory device and/or voltage level of the first external supply voltage.

Accordingly, the internal voltage generating circuit according to embodiments of the inventive concepts may be insensitive to a change in an external supply voltage and may have low power consumption.

According to another example embodiment, there is provided a semiconductor memory device including an internal voltage generating circuit configured to receive a first supply voltage and a second supply voltage, and generate a first internal voltage and a second internal voltage using one more voltage generators, the internal voltage generating circuit including a control circuit, the control circuit configured to generate at least one control signal that selectively activates the one or more voltage generators; a driving circuit configured to selectively output one of the first internal voltage and the second internal voltage based on at least one control signal; and a memory cell array configured to receive the selected internal voltage from the driving circuit, the selected internal voltage having a voltage level that is maintained if a voltage level of the first supply voltage changes.

### BRIEF DESCRIPTION OF THE DRAWINGS

The foregoing and other features and advantages of the inventive concepts will be apparent from the more particular description of example embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a block diagram of an internal voltage generating circuit in accordance with an embodiment of the inventive concepts;

FIG. 2 is a circuit diagram of an example of a first voltage generating circuit included in the internal voltage generating circuit of FIG. 1;

FIG. 3 is a circuit diagram of an example of a second voltage generating circuit included in the internal voltage generating circuit of FIG. 1;

FIG. 4 is a circuit diagram of an example of a third voltage generating circuit included in the internal voltage generating circuit of FIG. 1;

FIG. 5 is a block diagram of an internal voltage generating circuit in accordance with another embodiment of the inventive concepts;

FIG. 6 is a block diagram of an internal voltage generating circuit in accordance with still another embodiment of the inventive concepts;

FIG. 7 is a block diagram of an internal voltage generating circuit in accordance with yet another embodiment of the inventive concepts;

FIG. 8 is a block diagram of an example of a semiconductor memory device including an internal voltage generating circuit in accordance with embodiments of the inventive concepts;

FIG. 9 is a circuit diagram of an example of a sense amplifier and a sense amplifier driving circuit included in the semiconductor memory device of FIG. 8;

FIGS. 10 and 11 are timing diagrams illustrating sense amplifier control signals applied to the sense amplifier driving circuit shown in FIG. 9;

FIG. 12 is a block diagram of an example of a memory system including a semiconductor memory device in accordance with embodiments of the inventive concepts;

FIG. 13 is a diagram of an example of a stacked semiconductor device including a semiconductor memory device including an internal voltage generating circuit according to embodiments of the inventive concepts;

FIG. 14 is a block diagram of another example of a memory system including a semiconductor memory device in accordance with embodiments of the inventive concepts;

FIG. 15 is a block diagram of an example of an electronic system in which a semiconductor memory device including internal voltage generating circuit is included in accordance with embodiments of the inventive concepts; and

FIG. 16 is a flowchart illustrating a method of generating an internal voltage in accordance with embodiments of the inventive concepts.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

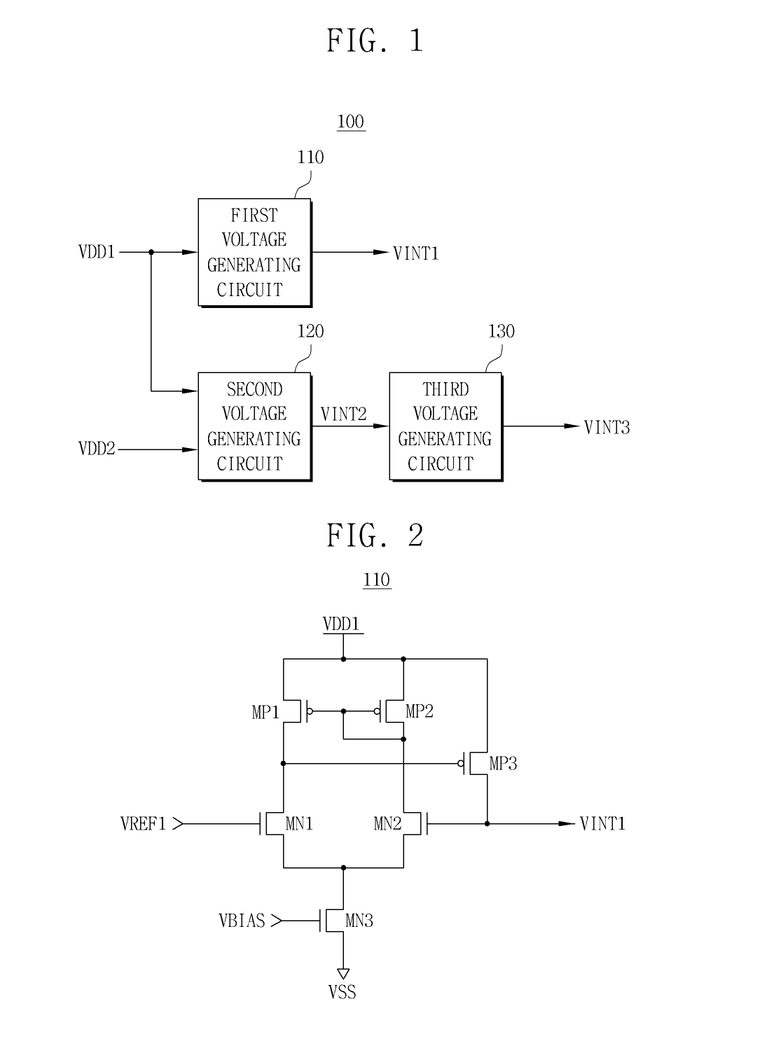

FIG. 1 is a block diagram of an internal voltage generating circuit 100 in accordance with an embodiment of the inventive concepts.

Referring to FIG. 1, the internal voltage generating circuit 100 may include a first voltage generating circuit 110, a second voltage generating circuit 120, and a third voltage generating circuit 130.

The first voltage generating circuit 110 stabilizes a first external supply voltage VDD1 to generate a first internal voltage VINT1. The second voltage generating circuit 120 stabilizes the first external supply voltage VDD1 and a second external supply voltage VDD2 to generate a second internal voltage VINT2 having a voltage level higher than the first internal voltage VINT1. The third voltage generating circuit 130 stabilizes the second internal voltage VINT2 to generate a third internal voltage VINT3 having a voltage level lower than the second internal voltage VINT2.

The first voltage generating circuit 110, the second voltage generating circuit 120, and the third voltage generating circuit 130 may be activated in response to an operating mode of a semiconductor memory device. Further, the first voltage generating circuit 110, the second voltage generating circuit 120, and the third voltage generating circuit 130 may be activated in response to a voltage level of the first external supply voltage VDD1.

FIG. 2 is a circuit diagram of an example of a first voltage generating circuit 110 included in the internal voltage generating circuit 100 of FIG. 1

Referring to FIG. 2, the first voltage generating circuit 110 may include PMOS transistors MP1, MP2 and MP3 and NMOS transistors MN1, MN2 and MN3. The first PMOS transistor MP1 has a source to which the first external supply voltage VDD1 is applied. The second PMOS transistor MP2 has a source to which the first external supply voltage VDD1 is applied, and a gate and drain commonly connected to a gate of the first PMOS transistor MP1. The first NMOS transistor MN1 has a drain connected to a drain of the first PMOS transistor MP1, and a gate to which a reference voltage VREF1 is applied. The second NMOS transistor MN2 has a drain connected to the drain of the second PMOS transistor MP2, a source connected to a source of the first NMOS transistor MN1, and a gate from which the first internal voltage VINT1 is output. The third NMOS transistor MN3 has a drain connected to the source of the first NMOS transistor MN1 and the source of the second NMOS transistor MN2, a gate to which a bias voltage VBIAS is applied, and a source connected to a low supply voltage VSS. The third PMOS transistor MP3 has a gate connected to the drain of the first PMOS transistor MP1, a source to which the first external supply voltage VDD1 is applied, and a drain connected to a gate of the second NMOS transistor MN2.

The first voltage generating circuit 110 having the structure of FIG. 1 may stabilize the first external supply voltage VDD1 to output the first internal voltage VINT1.

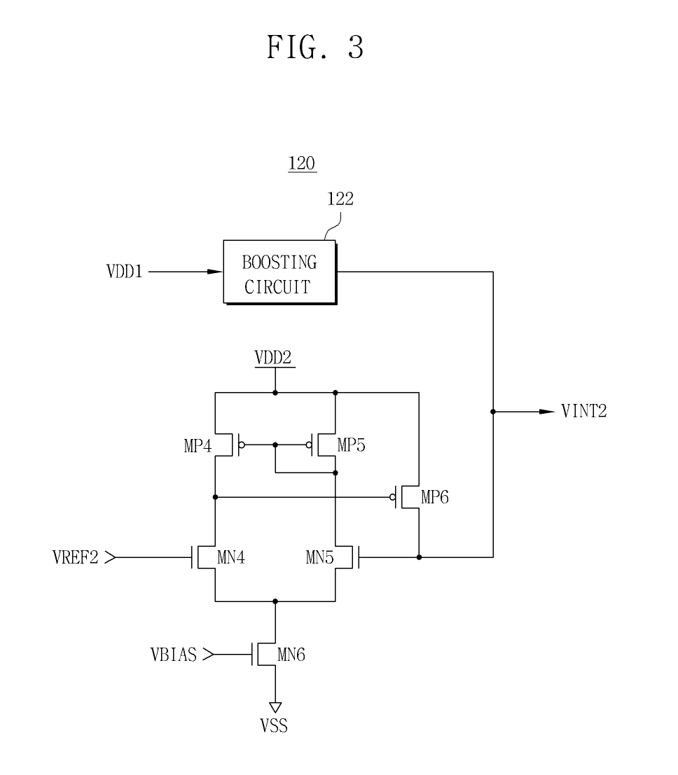

FIG. 3 is a circuit diagram of an example of a second voltage generating circuit 120 included in the internal voltage generating circuit 100 of FIG. 1

Referring to FIG. 3, the second voltage generating circuit 120 may include a boosting circuit 122, PMOS transistors MP4, MP5 and MP6, and NMOS transistors MN4, MN5 and MN6.

The first PMOS transistor MP4 has a source to which the first external supply voltage VDD1 is applied. The second PMOS transistor MP5 has a source to which the second external supply voltage VDD2 is applied, and a gate and drain commonly connected to a gate of the first PMOS transistor MP4. The first NMOS transistor MN4 has a drain connected to a drain of the first PMOS transistor MP4, and a gate to which a reference voltage VREF2 is applied. The second NMOS transistor MN5 has a drain connected to the drain of the second PMOS transistor MP5, a source connected to a source of the first NMOS transistor MN4, and a gate from which a second internal voltage VINT2 is output. The third NMOS transistor MN6 has a drain connected to the source of the first NMOS transistor MN4 and the source of the second NMOS transistor MN5, a gate to which a bias voltage VBIAS is applied, and a source connected to a low supply voltage VSS. The third PMOS transistor MP6 has a gate connected to the drain of the first PMOS transistor MP4, a source to which the second external supply voltage VDD2 is applied, and a drain connected to a gate of the second NMOS transistor MN5. An output terminal of the boosting circuit 122 is electrically connected to a gate of the second NMOS transistor MN5, and the second internal voltage VINT2 is output through the output terminal of the boosting circuit 122.

The second voltage generating circuit 120 having the structure of FIG. 3 may increase the voltage level of the first external supply voltage VDD1 and stabilize the second external supply voltage VDD2 to output the second internal voltage VINT2. The second voltage generating circuit 120 of FIG. 3 may selectively output an output signal of the boosting circuit 122, and an output signal of the voltage generating circuit comprised of PMOS transistors MP4, MP5 and MP6, and NMOS transistors MN4, MN5 and MN6 in response to an enable signal applied from the exterior.

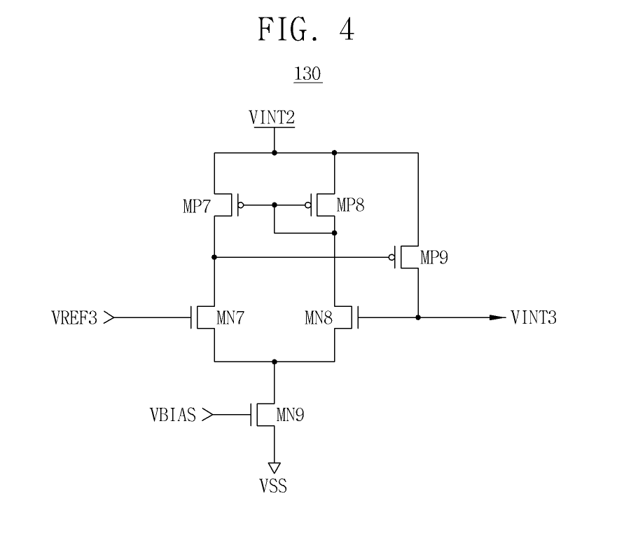

FIG. 4 is a circuit diagram of an example of a third voltage generating circuit 130 included in the internal voltage generating circuit 100 of FIG. 1.

Referring to FIG. 4, the third voltage generating circuit 130 may include PMOS transistors MP7, MP8 and MP9 and NMOS transistors MN7, MN8 and MN9. The first PMOS transistor MP7 has a source to which the second internal voltage VINT2 is applied. The second PMOS transistor MP8 has a source to which the second internal voltage VINT2 is applied, and a gate and drain commonly connected to a gate of the first PMOS transistor MP7. The first NMOS transistor MN7 has a drain connected to a drain of the first PMOS transistor MP7, and a gate to which a reference voltage VREF3 is applied. The second NMOS transistor MN8 has a drain connected to the drain of the second PMOS transistor MP8, a source connected to a source of the first NMOS transistor MN7, and a gate from which a third internal voltage VINT3 is output. The third NMOS transistor MN9 has a drain connected to the source of the first NMOS transistor MN7 and the source of the second NMOS transistor MN8, a gate to which a bias voltage VBIAS is applied, and a source connected to a low supply voltage VSS. The third PMOS transistor MP9 has a gate connected to the drain of the first PMOS transistor MP7, a source to which the second internal voltage VINT2 is applied, and a drain connected to a gate of the second NMOS transistor MN8.

The third voltage generating circuit 130 having the structure of FIG. 4 may stabilize the second internal voltage VINT2 to output the third internal voltage VINT3.

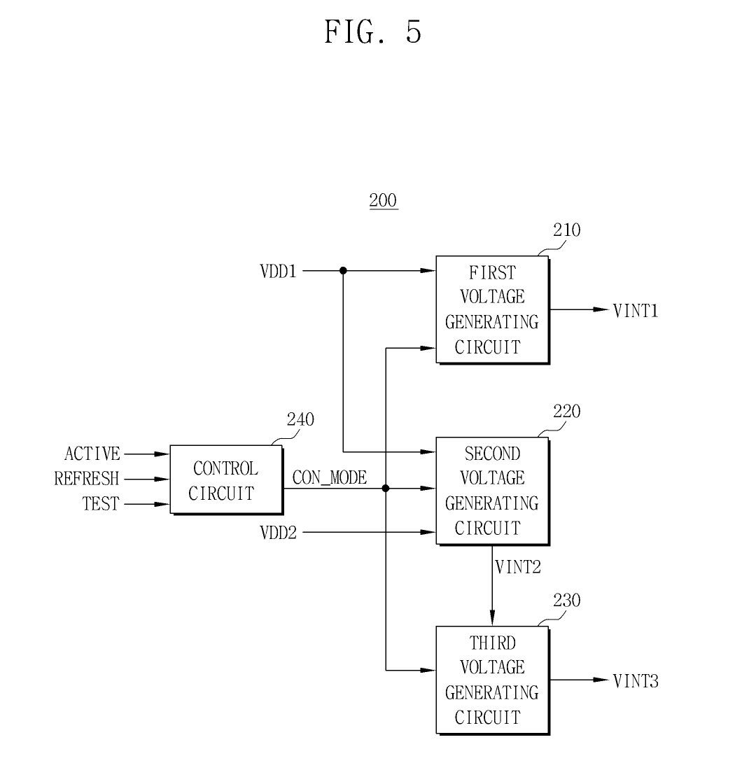

FIG. 5 is a block diagram of an internal voltage generating circuit 200 in accordance with another embodiment of the inventive concepts.

Referring to FIG. 5, the internal voltage generating circuit 200 may include a first voltage generating circuit 210, a second voltage generating circuit 220, a third voltage generating circuit 230 and a control circuit 240.

The control circuit 240 generates an enable signal CON_MODE that activates the first voltage generating circuit 210, the second voltage generating circuit 220 and the third voltage generating circuit 230 based on operating mode signals of a semiconductor memory device. The operating mode signals of the semiconductor memory device may include an active command (ACTIVE), a refresh command (REFRESH), and a test command (TEST).

The first voltage generating circuit 210 stabilizes a first external supply voltage VDD1 to generate a first internal voltage VINT1. The second voltage generating circuit 220 stabilizes the first external supply voltage VDD1 and a second external supply voltage VDD2 to generate a second internal voltage VINT2 having a voltage level higher than the first internal voltage VINT1. The third voltage generating circuit 230 stabilizes the second internal voltage VINT2 to generate a third internal voltage VINT3 having a voltage level lower than the second internal voltage VINT2.

In the internal voltage generating circuit 200 of FIG. 5, all or part of the first voltage generating circuit 210, the second voltage generating circuit 220 and the third voltage generating circuit 230 may be activated in response to an operating mode of a semiconductor memory device. For example, in the active mode, all of the first voltage generating circuit 210, the second voltage generating circuit 220 and the third voltage generating circuit 230 may be activated. However, in the test mode, the first voltage generating circuit 210 may be activated, but the second voltage generating circuit 220 and the third voltage generating circuit 230 may not be activated. Further, in the refresh mode, the first voltage generating circuit 210 and the second voltage generating circuit 220 may be activated, and may selectively activate a boosting circuit 122 shown in FIG. 3 and a voltage generating circuit comprised of PMOS transistors MP4, MP5 and MP6, and NMOS transistors MN4, MN5 and MN6.

Accordingly, the semiconductor memory device including the internal voltage generating circuit 200 of FIG. 5 may have small power consumption.

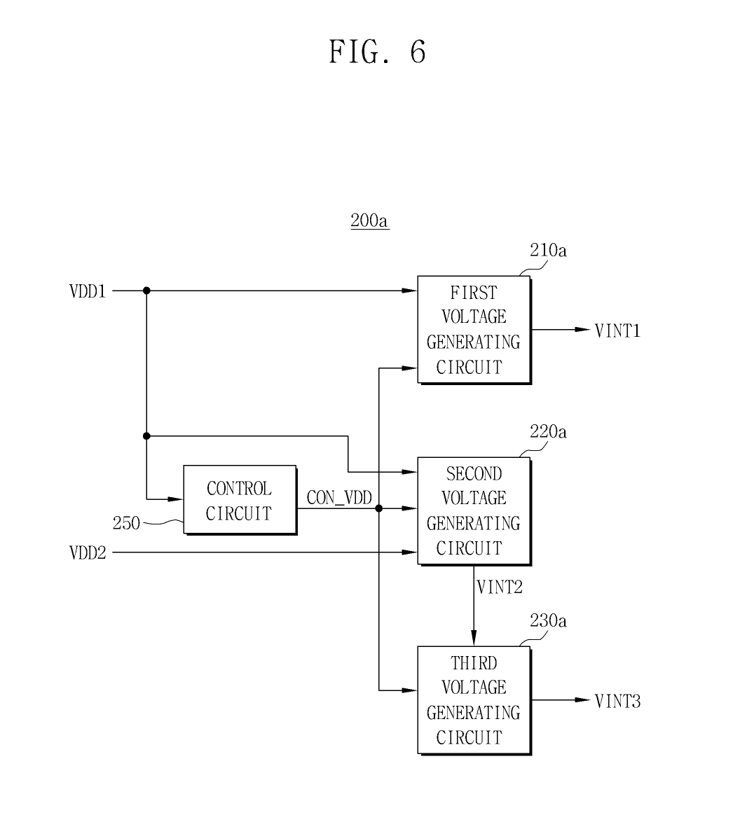

FIG. 6 is a block diagram of an internal voltage generating circuit 200a in accordance with still another embodiment of the inventive concepts.

Referring to FIG. 6, the internal voltage generating circuit 200a may include a first voltage generating circuit 210a, a second voltage generating circuit 220a, a third voltage generating circuit 230a, and a control circuit 250.

The control circuit 250 generates an enable signal CON_VDD that activates the first voltage generating circuit 210a, the second voltage generating circuit 220a and the third voltage generating circuit 230a based on a voltage level of the first external supply voltage VDD1.

The first voltage generating circuit 210a stabilizes a first external supply voltage VDD1 to generate a first internal voltage VINT1. The second voltage generating circuit 220a stabilizes the first external supply voltage VDD1 and a second external supply voltage VDD2 to generate a second internal voltage VINT2 having a voltage level higher than the first internal voltage VINT1. The third voltage generating circuit 230a stabilizes the second internal voltage VINT2 to generate a third internal voltage VINT3 having a voltage level lower than the second internal voltage VINT2.

In the internal voltage generating circuit 200a of FIG. 6, the first voltage generating circuit 210a, the second voltage generating circuit 220a and the third voltage generating circuit 230a may be activated in response to the enable signal CON_VDD. Therefore, the first voltage generating circuit 210a, the second voltage generating circuit 220a and the third voltage generating circuit 230a may be activated all together, or part of them may be activated according to the voltage level of the first external supply voltage VDD1. For example, when the voltage level of the first external supply voltage VDD1 is higher than a first level, only the first voltage generating circuit 210a may be activated, but when the voltage level of the first external supply voltage VDD1 is lower than the first level, all of the first voltage generating circuit 210a, the second voltage generating circuit 220a and the third voltage generating circuit 230a may be activated. Here, the first level may be a voltage level of the first internal voltage VINT1 that is generated based on the first external supply voltage VDD1 and enough to drive an internal circuit.

Accordingly, the semiconductor memory device including the internal voltage generating circuit 200a of FIG. 6 may have small power consumption.

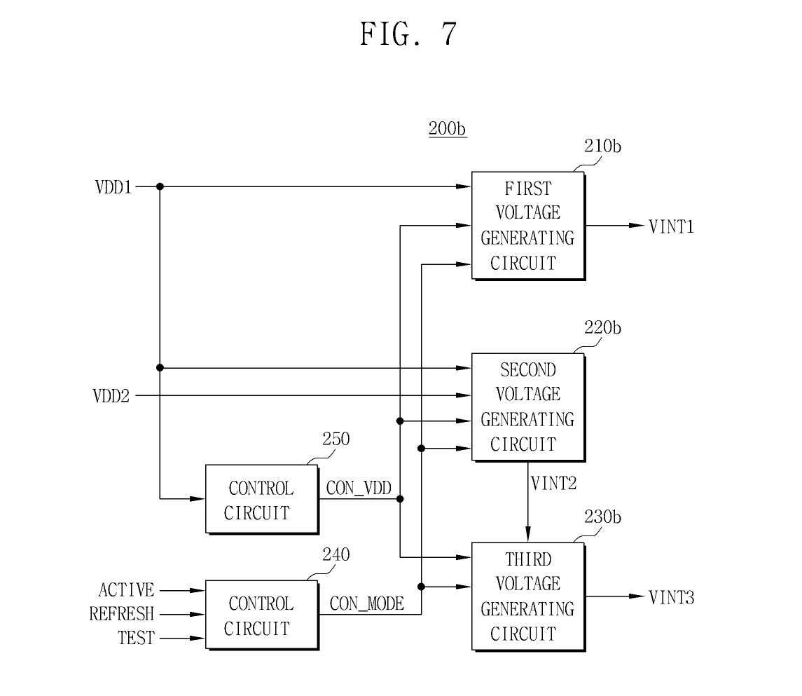

FIG. 7 is a block diagram of an internal voltage generating circuit 200b in accordance with yet another embodiment of the inventive concepts.

Referring to FIG. 7, the internal voltage generating circuit 200b may include a first voltage generating circuit 210b, a second voltage generating circuit 220b, a third voltage generating circuit 230b, a first control circuit 240 and a second control circuit 250.

The first control circuit 240 generates a first enable signal CON_MODE that activates the first voltage generating circuit 210, the second voltage generating circuit 220 and the third voltage generating circuit 230 based on operating mode signals of a semiconductor memory device. The second control circuit 250 generates a second enable signal CON_VDD that activates the first voltage generating circuit 210b, the second voltage generating circuit 220b and the third voltage generating circuit 230b based on a voltage level of the first external supply voltage VDD1. The operating mode signals of the semiconductor memory device may include an active command (ACTIVE), a refresh command (REFRESH), and a test command (TEST).

The first voltage generating circuit 210b stabilizes the first external supply voltage VDD1 to generate a first internal voltage VINT1. The second voltage generating circuit 220b stabilizes the first external supply voltage VDD1 and a second external supply voltage VDD2 to generate a second internal voltage VINT2 having a voltage level higher than the first internal voltage VINT1. The third voltage generating circuit 230b stabilizes the second internal voltage VINT2 to generate a third internal voltage VINT3 having a voltage level lower than the second internal voltage VINT2.

In the internal voltage generating circuit 200b of FIG. 7, all of the first voltage generating circuit 210b, the second voltage generating circuit 220b and the third voltage generating circuit 230b may be activated in response to the first enable signal CON_MODE and the second enable signal CON_VDD. Therefore, the first voltage generating circuit 210, the second voltage generating circuit 220 and the third voltage generating circuit 230 may be activated all together, or part of them may be activated according to an operating mode of a semiconductor memory device. For example, in the active mode, all of the first voltage generating circuit 210b, the second voltage generating circuit 220b and the third voltage generating circuit 230b may be activated. However, in the test mode, the first voltage generating circuit 210b may be activated, but the second voltage generating circuit 220b and the third voltage generating circuit 230b may not be activated. Further, the first voltage generating circuit 210b, the second voltage generating circuit 220b and the third voltage generating circuit 230b may be activated in response to the second enable signal CON_VDD. Therefore, the first voltage generating circuit 210b, the second voltage generating circuit 220b and the third voltage generating circuit 230b may be activated all together, or part of them may be activated according to the voltage level of the first external supply voltage VDD1. For example, when the voltage level of the first external supply voltage VDD1 is higher than a first level, only the first voltage generating circuit 210b may be activated, but when the voltage level of the first external supply voltage VDD1 is lower than the first level, all of the first voltage generating circuit 210b, the second voltage generating circuit 220b and the third voltage generating circuit 230b may be activated.

Accordingly, the semiconductor memory device including the internal voltage generating circuit 200b of FIG. 7 may have small power consumption.

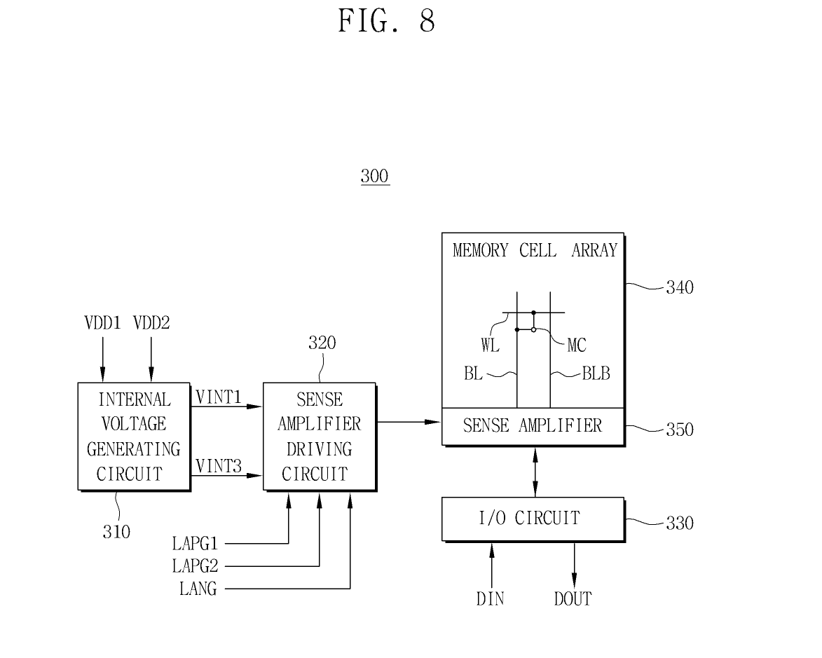

FIG. 8 is a block diagram of an example of a semiconductor memory device including an internal voltage generating circuit in accordance with embodiments of the inventive concepts.

Referring to FIG. 8, the semiconductor memory device 300 may include an internal voltage generating circuit 310, a sense amplifier driving circuit 320, I/O circuit 330, a memory cell array 340 and a bit line sense amplifier 350.

The memory cell array 340 includes a plurality of word lines, a plurality of bit lines, and memory cells MC disposed at an intersection of each of the word lines (WL) and each of the bit lines (BL, BLB). The bit line sense amplifier 350 amplifies a voltage between the bit lines (BL, BLB). The internal voltage generating circuit 310 generates a first internal supply voltage VINT1 and a third internal supply voltage VINT3 based on a first external supply voltage VDD1 and a second external supply voltage VDD2. The sense amplifier driving circuit 320 provides the first internal supply voltage VINT1 or the third internal supply voltage VINT3 to the bit line sense amplifier 350 in response to sense amplifier control signal LAPG1, LAPG2 and LANG. The internal voltage generating circuit 310 may have circuit structures according to example embodiments shown in FIGS. 1, 5 and 6.

Accordingly, the semiconductor memory device shown in FIG. 8 may generate stable internal voltage regardless of a change in the first external supply voltage VDD1. The semiconductor memory device semiconductor memory device may accomplish this by selectively outputting either the first internal supply voltage VINT1 or the third internal supply voltage VINT3. The first internal supply voltage VINT1 being a stable version of the first external supply voltage. The third internal supply voltage VINT3 being a stable version of a boosted version of the first internal supply voltage VINT1 or a stable version of the second external supply voltage VDD2. Further the semiconductor memory device shown in FIG. 8 has a relatively small power consumption.

The semiconductor memory device 300 of FIG. 8 may include a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

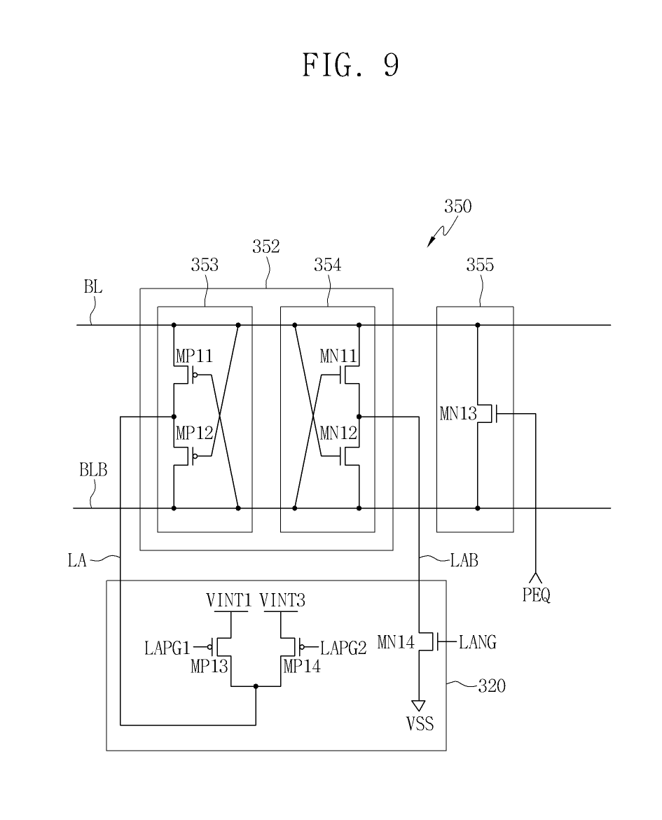

FIG. 9 is a circuit diagram of an example of a sense amplifier 350 and a sense amplifier driving circuit 320 included in the semiconductor memory device 300 of FIG. 8.

Referring to FIG. 9, the sense amplifier 350 may include a sense amplifier unit 352 and an equalizer unit 355. The sense amplifier unit 352 may include a P-type sense amplifier unit 353 and an N-type sense amplifier unit 354.

The sense amplifier driving circuit 320 may include a first PMOS transistor MP13, a second PMOS transistor MP14, and a first NMOS transistor MN14.

The first PMOS transistor MP13 provides the first internal voltage VINT1 to the P-type sense amplifier unit 353 through a line LA in response to a first sense amplifier control signal LAPG1. The second PMOS transistor MP14 provides the third internal voltage VINT3 to the P-type sense amplifier unit 353 through the line LA in response to a second sense amplifier control signal LAPG2. The first NMOS transistor MN14 provides the low supply voltage VSS to the N-type sense amplifier unit 354 through a line LAB in response to a third sense amplifier control signal LANG.

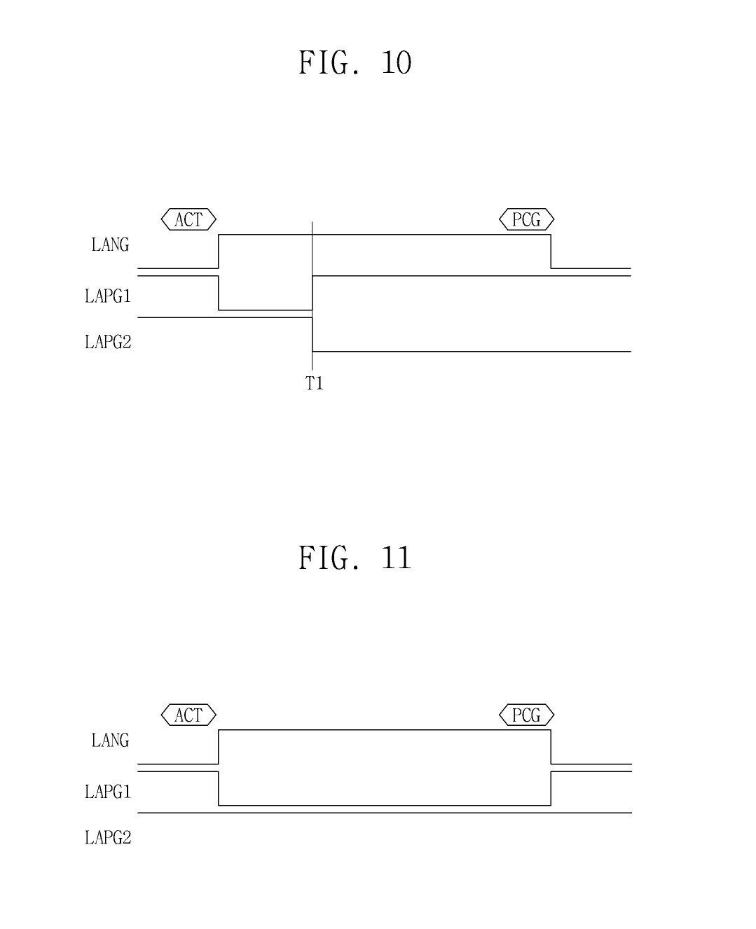

FIGS. 10 and 11 are timing diagrams illustrating sense amplifier control signals applied to the sense amplifier driving circuit 320 shown in FIG. 9.

Referring to FIGS. 9 and 10, when an active command ACT is generated, the third sense amplifier control signal LANG becomes enabled with logic high, and the first sense amplifier control signal LAPG1 becomes enabled with logic low. At time point T1, the first sense amplifier control signal LAPG1 becomes disabled with logic high, and the second sense amplifier control signal LAPG2 becomes enabled with logic low. The third sense amplifier control signal LANG becomes disabled in response to a pre-charge command PCG. The timing diagram of FIG. 10 illustrates these control signals. Applying the control signals of FIG. 10 to the sense amplifier driving circuit 320 shown in FIG. 9 results in the sense amplifier driving circuit 320 driving the sense amplifier 350 using the first internal voltage VINT1 at the initial time of operation, and driving the sense amplifier 350 using the third internal voltage VINT3 after a certain time has passed.

Referring to FIGS. 9 and 11, when an active command ACT is generated, the third sense amplifier control signal LANG becomes enabled with logic high, and the first sense amplifier control signal LAPG1 becomes enabled with logic low. The first sense amplifier control signal LAPG1 and the third sense amplifier control signal LANG maintain an enable state until the pre-charge command PCG is generated. The second sense amplifier control signal LAPG2 maintains logic high state and is disabled all the time. The timing diagram of FIG. 11 illustrates these control signals. Applying the control signals of FIG. 11 to the sense amplifier driving circuit 320 shown in FIG. 9 results in the first PMOS transistor MP13 being enabled while the second PMOS transistor MP14 is disabled. Thus, the first internal voltage VINT1 is used but the third internal voltage VINT3 is not used.

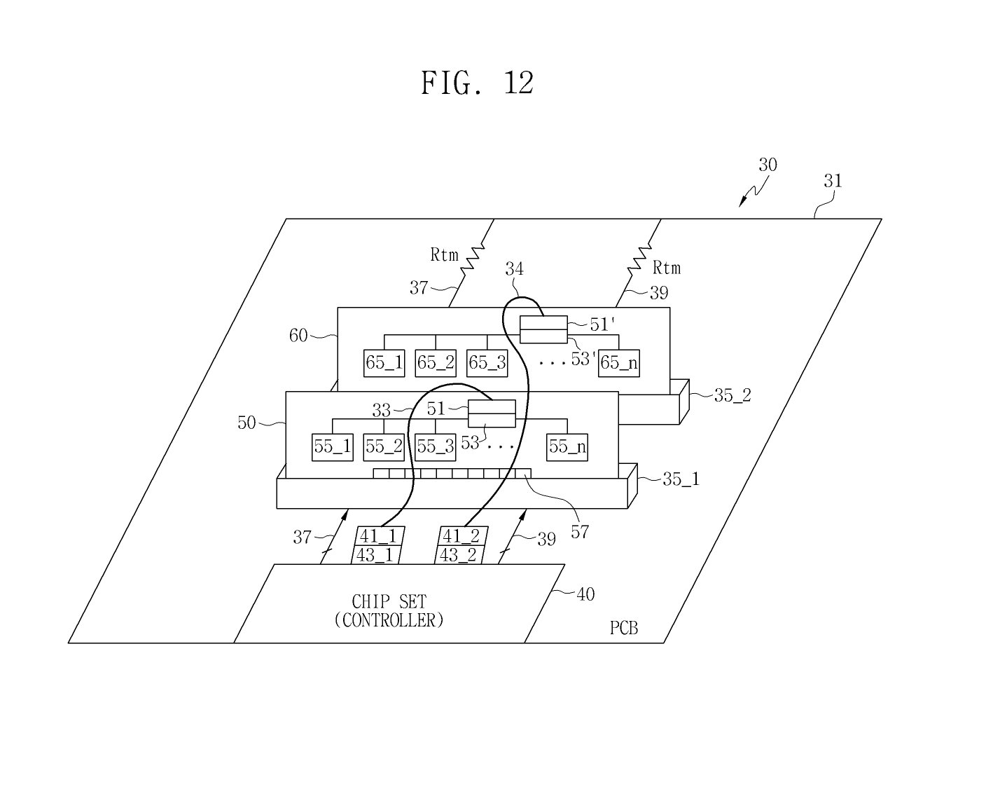

FIG. 12 is a block diagram of an example of a memory system 30 including a semiconductor memory device in accordance with embodiments of the inventive concepts.

Referring to FIG. 12, the memory system 30 may include a motherboard 31, a chip set (or a controller) 40, slots 35_1 and 35_2, memory modules 50 and 60, and transmission lines 33 and 34. Buses 37 and 39 connect the chip set 40 with the slots 35_1 and 35_2. A terminal resistor Rtm may terminate each of the buses 37 and 39 on a PCB of the motherboard 31.

For convenience, in FIG. 12, only two slots 35_1 and 35_2 and two memory modules 50 and 60 are shown. However, the memory system 30 may include an arbitrary number of slots and memory modules.

The chip set 40 may be mounted on the PCB of the motherboard 31, and control the operation of the memory system 30. The chip set 40 may include connectors 41_1 and 41_2 and converters 43_1 and 43_2.

The converter 43_1 receives parallel data generated by the chip set 40, converts the parallel data to serial data, and outputs the serial data to the transmission line 33 via the connector 41_1. The converter 43_1 receives serial data via the transmission line 33, converts the serial data to parallel data, and outputs the parallel data to the chip set 40.

The converter 43_2 receives parallel data generated by the chip set 40, converts the parallel data to serial data, and outputs the serial data to the transmission line 34 via the connector 41_2. The converter 43_2 receives serial data via the transmission line 34, converts the serial data to parallel data, and outputs the parallel data to the chip set 40. The transmission lines 33 and 34 included in the memory system 30 may be a plurality of optical fibers.

The memory module 50 may include a plurality of memory devices 55_1 to 55_{—}n, a first connector 57, a second connector 51, and a converter 53. The memory module 60 may include a plurality of memory devices 65_1 to 65_{—}n, a first connector 57′, a second connector 51′, and a converter 53′.

The first connector 57 may transfer low-speed signals received from the chip set 40 to the memory devices 55_1 to 55_{—}n, and the second connector 51 may be connected to the transmission line 33 for transferring high-speed signals.

The converter 53 receives serial data via the second connector 51, converts the serial data to parallel data, and outputs the parallel data to the memory devices 55_1 to 55_{—}n. Further, the converter 53 receives parallel data from the memory devices 55_1 to 55_{—}n, converts the parallel data to serial data, and outputs the serial data to the second connector 51.

The memory devices 55_1 to 55_{—}n and 65_1 to 65_{—}n may include a semiconductor memory device according to embodiments of the inventive concepts. Therefore, the memory devices 55_1 to 55_{—}n and 65_1 to 65_{—}n may include an internal voltage generating circuit according to embodiments of the inventive concepts.

The memory devices 55_1 to 55_{—}n and 65_1 to 65_{—}n may be a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

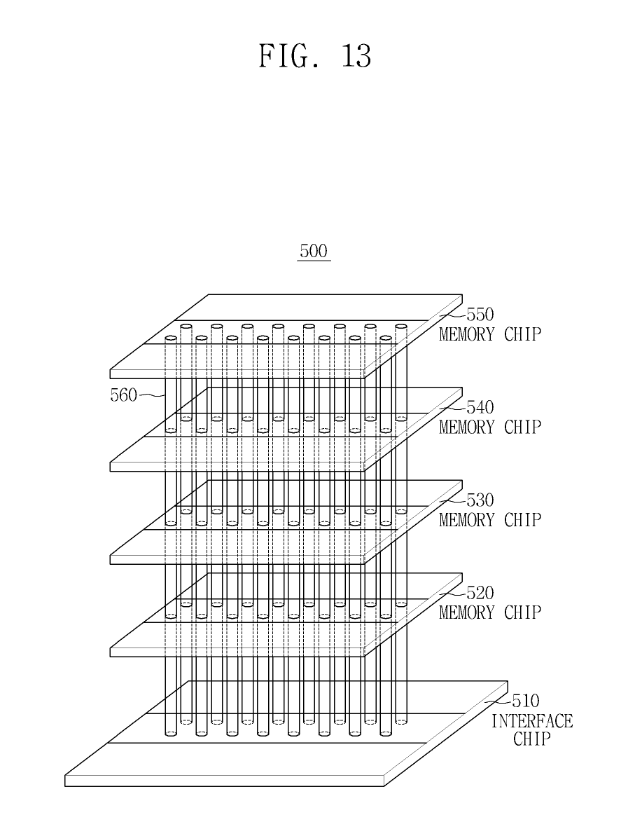

FIG. 13 is a diagram of an example of a stacked semiconductor device 500 including a semiconductor memory device including an internal voltage generating circuit according to embodiments of the inventive concepts.

Referring to FIG. 13, the stacked semiconductor device 500 may include an interface chip 510, and memory chips 520, 530, 540 and 550 which are electrically connected through through-silicon vias 560. Although the through-silicon vias 560 disposed in two rows are shown in FIG. 13, the stack semiconductor device 500 may include any number of through-silicon vias.

The memory chips 520, 530, 540 and 550 included in the stacked semiconductor device 500 may include the internal voltage generating circuit in accordance with the embodiments as described above. The interface chip 510 performs an interface between the memory chips 520, 530, 540 and 550 and external devices.

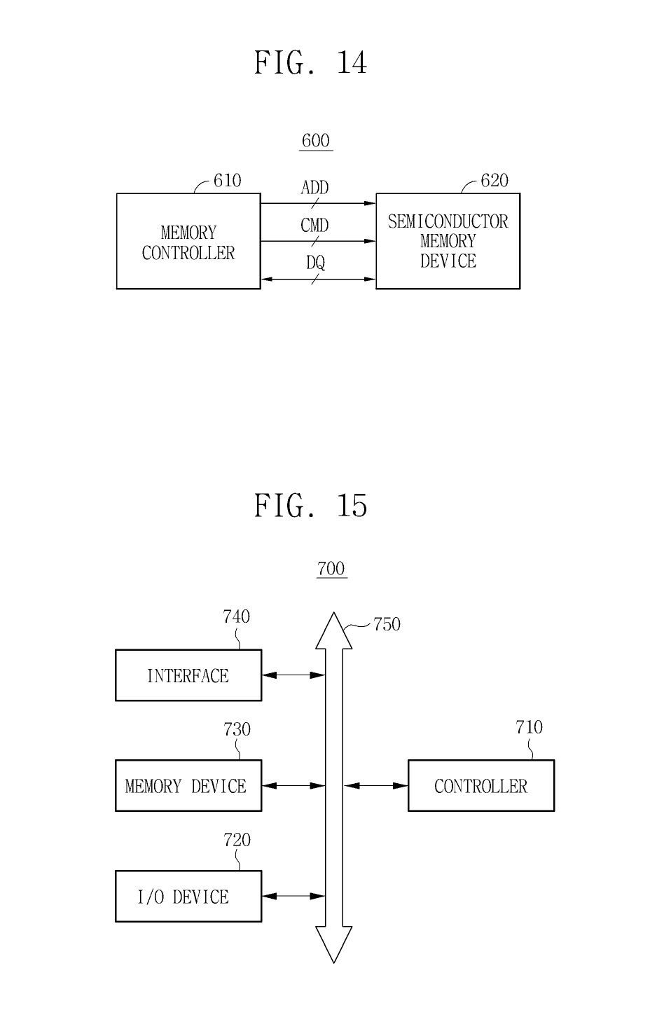

FIG. 14 is a block diagram of another example of a memory system 600 including a semiconductor memory device in accordance with embodiments of the inventive concepts.

Referring to FIG. 14, the memory system 600 includes a memory controller 610 and a semiconductor memory device 620.

The memory controller 610 generates address signals ADD and command signals CMD, and provides the address signals ADD and the command signals CMD to the semiconductor memory device 620 through buses. Data DQ may be transmitted from the memory controller 610 to the semiconductor memory device 620 through the buses, or transmitted from the stacked semiconductor memory device 620 to the memory controller 610 through the buses.

The semiconductor memory device 620 may include the internal voltage generating circuit according to embodiments of the inventive concepts.

FIG. 15 is a block diagram of an example of an electronic system 700 in which a semiconductor memory device including internal voltage generating circuit is included in accordance with embodiments of the inventive concepts.

Referring to FIG. 15, the electronic system 700 in accordance with embodiment may include a controller 710, an input and output device 720, a memory device 730, an interface 740, and a bus 750. The memory device 730 may be a semiconductor memory device including the internal voltage generating circuit in accordance with embodiments of the inventive concepts. The bus 750 may function to provide a path in which data is mutually moved among the controller 710, the input and output device 720, the memory device 730, and the interface 740.

The controller 710 may include any one of logic devices that can perform functions of at least one of a microprocessor, a digital signal processer, and a microcontroller, or functions similar to those. The input and output device 720 may include at least one selected from a key pad, key board, and a display device. The memory device 730 may function to store data and/or instructions performed by the controller 710.

The memory device 730 may include a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof. The memory device 730 may be the semiconductor memory device including the internal voltage generating circuit in accordance with embodiments of the inventive concepts.

The interface 740 may function to transmit/receive data to/from a communication network. The interface 740 may include an antenna, wired or wireless transceivers or the like to transmit and receive data by wires or wirelessly. In addition, the interface 740 can include optical fibers to transmit and receive data through the optical fibers. The electronic system 700 may be further provided with an application chipset, a camera image processor, and an input and output device.

The electronic system 700 may be implemented as a mobile system, personal computer, an industrial computer, or a logic system that can perform various functions. For example, the mobile system may be any one of a personal digital assistant (PDA), a portable computer, a web tablet, a mobile phone, a wireless phone, a laptop computer, a memory card, a digital music system, and an information transmitting/receiving system. If the electronic system 700 is an apparatus that can perform wireless communication, the electronic system 3000 may be used in a communication system such as a Code Division multiple Access (CDMA), a Global System for Mobile communication (GSM), a North American Digital Cellular (NADC), an Enhanced-Time Division Multiple Access (E-TDMA), a Wideband Code Division Multiple Access (WCDMA), or a CDMA 2000.

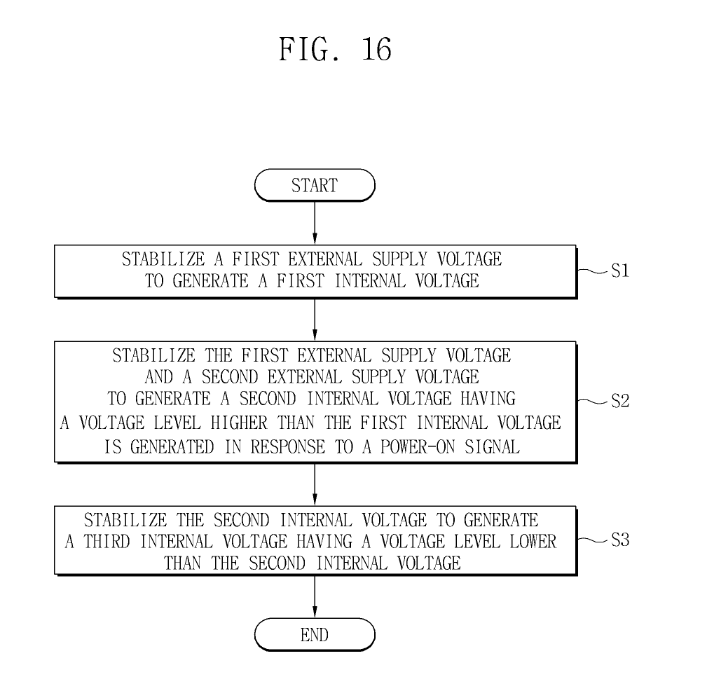

FIG. 16 is a flowchart illustrating a method of generating an internal voltage in accordance with embodiments of the inventive concepts.

Referring to FIG. 16, the method of generating an internal voltage in accordance with embodiments of the inventive concepts may include the following operations:

(1) Stabilize a first external supply voltage to generate a first internal voltage (S1).

(2) Stabilize the first external supply voltage and a second external supply voltage to generate a second internal voltage having a voltage level higher than the first internal voltage. A random code is generated in response to a power-on signal (S2).

(3) Stabilize the second internal voltage to generate a third internal voltage having a voltage level lower than the second internal voltage (S3).

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concepts as defined in the claims. In the claims, means-plus-function clauses are intended to cover the structures described herein as performing the recited function, and not only structural equivalents but also equivalent structures.

What is claimed is:

1. An internal voltage generating circuit, comprising:
a first voltage generating circuit configured to stabilize a first external supply voltage to generate a first internal voltage;
a second voltage generating circuit configured to selectively stabilize the first external supply voltage and a second external supply voltage to generate a second internal voltage having a voltage level higher than the first internal voltage; and
a third voltage generating circuit configured to stabilize the second internal voltage to generate a third internal voltage having a voltage level lower than the second internal voltage.

2. The circuit according to claim 1, wherein the second voltage generating circuit includes a boosting circuit configured to boost a voltage level of the first external supply voltage.

3. The circuit according to claim 1, wherein the first voltage generating circuit, the second voltage generating circuit, and the third voltage generating circuit are configured to be selectively activated in response to an operating mode of a semiconductor memory device.

4. The circuit according to claim 1, further comprising:
a control circuit configured to generate an enable signal that selectively activates at least one of the first voltage generating circuit, the second voltage generating circuit, and the third voltage generating circuit based on operating mode signals of a semiconductor memory device.

5. The circuit according to claim 4, wherein the operating mode signals of the semiconductor memory device includes an active command, a refresh command, and a test command.

6. The circuit according to claim 1, wherein the first voltage generating circuit, the second voltage generating circuit, and the third voltage generating circuit are configured to be selectively activated in response to a voltage level of the first external supply voltage.

7. The circuit according to claim 1, further comprising:
a control circuit configured to generate an enable signal that selectively activates at least one of the first voltage generating circuit, the second voltage generating circuit, and the third voltage generating circuit based on a voltage level of the first external supply voltage.

8. The circuit according to claim 1, wherein the first voltage generating circuit, the second voltage generating circuit, and the third voltage generating circuit are configured to be selectively activated in response to an operating mode of a semiconductor memory device and a voltage level of the first external supply voltage.

9. The circuit according to claim 1, further comprising:
a first control circuit configured to generate a first enable signal that selectively activates at least one of the first voltage generating circuit, the second voltage generating circuit, and the third voltage generating circuit based on operating mode signals of a semiconductor memory device; and
a second control circuit configured to generate a second enable signal that selectively activates at least one of the first voltage generating circuit, the second voltage generating circuit, and the third voltage generating circuit based on a voltage level of the first external supply voltage.

10. A semiconductor memory device comprising:
a memory cell array including a plurality of word lines, a plurality of bit lines, and memory cells disposed at an intersection of each of the word lines and each of the bit lines;
a bit line sense amplifier configured to amplify a voltage between the bit lines;
an internal voltage generating circuit including,
a first voltage generating circuit configured to stabilize a first external supply voltage to generate a first internal voltage,
a second voltage generating circuit configured to stabilize the first external supply voltage and a second external supply voltage to generate a second internal voltage having a voltage level higher than the first internal voltage, and
a third voltage generating circuit configured to stabilize the second internal voltage to generate a third internal voltage having a voltage level lower than the second internal voltage; and
a sense amplifier driving circuit configured to provide the first internal supply voltage or the second internal supply voltage to the bit line sense amplifier.

11. The semiconductor memory device according to claim 10, wherein the internal voltage generating circuit further comprises:
a control circuit configured to generate an enable signal that selectively activates at least one of the first voltage generating circuit, the second voltage generating circuit, and the third voltage generating circuit based on operating mode signals of a semiconductor memory device.

12. The semiconductor memory device according to claim 11, wherein the operating mode signals of the semiconductor memory device includes an active command, a refresh command, and a test command.

13. The semiconductor memory device according to claim 10, wherein the internal voltage generating circuit further comprises:
a control circuit configured to generate an enable signal that selectively activates at least one of the first voltage generating circuit, the second voltage generating circuit, and the third voltage generating circuit based on a voltage level of the first external supply voltage.

14. The semiconductor memory device according to claim 10, further comprising:
a first control circuit configured to generate a first enable signal that selectively activates at least one of the first voltage generating circuit, the second voltage generating circuit, and the third voltage generating circuit based on operating mode signals of a semiconductor memory device; and
a second control circuit configured to generate a second enable signal that selectively activates at least one of the first voltage generating circuit, the second voltage generating circuit, and the third voltage generating circuit based on a voltage level of the first external supply voltage.

15. The semiconductor memory device according to claim 10, wherein the semiconductor memory device is a stacked memory device in which a plurality of chips communicates data and control signals by a through-silicon-via (TSV).

16. A semiconductor memory device comprising:
an internal voltage generating circuit configured to receive a first supply voltage and a second supply voltage, and generate a first internal voltage and a second internal voltage using one more voltage generators, the internal voltage generating circuit including a control circuit, the control circuit configured to generate at least one control signal that selectively activates the one or more voltage generators;
a driving circuit configured to selectively output one of the first internal voltage and the second internal voltage based on at least one driving signal; and
a memory cell array configured to receive the selected internal voltage from the driving circuit, the selected internal voltage having a voltage level that is maintained if a voltage level of the first supply voltage changes.

17. The semiconductor memory device according to claim 16, wherein the internal voltage generating circuit is configured to output stable versions of the first supply voltage and the second supply voltage as the first internal voltage and the second internal voltage, respectfully, by eliminating fluctuations in a voltage level of the first supply voltage and the second supply voltage.

18. The semiconductor memory device according to claim 16, wherein the internal voltage generating circuit is configured to,
output, as the first internal voltage, a stable version of the first supply voltage by eliminating fluctuations in a voltage level of the first supply voltage; and
output, as the second internal voltage, one of a non-boosted voltage and a boosted voltage, the boosted voltage being a modified voltage of the first supply voltage that eliminates fluctuations in a voltage level of the first supply voltage and boosts the voltage level of the first supply voltage, the non-boosted voltage being a modified voltage of the second supply voltage that eliminates fluctuations in a voltage level of the second supply voltage.
